(19) United States
(12) Patent Application Publication
(10) Pub. No.: US 2005/0032308 A1
(43) Pub. Date: Feb. 10, 2005

(54) Multi-bit vertical memory cell and method of fabricating the same

(76) Inventors: Ching-Nan Hsiao, Kaohsiung (TW); Chao-Sung Lai, Ilan (TW); Yung-Meng Huang, Taoyuan (TW)

Correspondence Address: QUINTERO LAW OFFICE, 1617 BROADWAY, 3RD FLOOR, SANTA MONICA, CA, 90404, US

(21) Appl. No.: 10/775,307

(22) Filed: Feb. 10, 2004

(30) Foreign Application Priority Data
Aug. 8, 2003 (TW) 92121763

(51) Int. Cl. H01L 21/336

(52) U.S. Cl. 438/257; 438/258; 438/261

(57) ABSTRACT

A multi-bit vertical memory cell and method of fabricating the same. The multi-bit vertical memory cell comprises a semiconductor substrate with a trench, a plurality of bit lines formed therein near its surface and the bottom trench respectively, a plurality of bit line insulating layers over each bit line, a silicon rich oxide layer conformably formed on the sidewall of the trench and the surface of the surface of the bit line insulating layer, and a word line over the silicon rich oxide layer, and the trench is filled with the word line.

### BACKGROUND OF THE INVENTION

1. Field of the Invention

The invention relates to a vertical memory cell, and more particularly to a vertical memory cell with at least two bits and a method for fabricating the same.

2. Description of the Related Art

Types of nonvolatile memory include electrically erasable and programmable read-only memory (EEPROM), which can be programmed and erased electrically with low power consumption and is capable of retaining data when powered off. A conventional flash memory comprises a floating gate and a control gate, both formed by doped polysilicon. When the flash memory is programmed, hot electrons are injected into the polysilicon floating gate and distributed evenly over the entire floating gate. If defects are present in the tunnel oxide layer under the polysilicon floating gate, however, the floating gate is susceptible to electron leakage, resulting in diminished memory device reliability.

In order to reduce the process steps and keep the cost, an NROM structure has recently been introduced. When the memory device is programmed with proper biases applied to the control gate and the source/drain region, hot electrons are generated in the channel near the drain region and injected into the charge trapping layer. The electron trapping property of silicon nitride causes injected electrons to localize in the charge trapping layer, rather than distribute evenly over the entire charge trapping layer. Consequently, the charge trapping region is quite small and thus less likely to be located on defects in the tunnel oxide layer. Memory device leakage is thereby reduced.

FIG. 1 is a cross-section showing a conventional NROM cell structure. This cell includes a semiconductor substrate 100 which has two separated bit lines (source and drain) 102, two bit line oxides 104 formed over each of the bit lines 102, respectively, and an ONO layer 112 having a silicon nitride layer 108 sandwiched between the bottom silicon oxide layer 106 and top silicon oxide layer 110 formed on the substrate 100 between bit line oxides 102. A gate conductive layer 114 (word line) lies on top of the bit line oxides 104 and the ONO layer 112.

The silicon nitride layer of the ONO structure 112 has two charge storage areas 107 and 109 to store charges during memory cell programming, wherein the charge storage areas 107 and 109 are adjacent to the bit lines 102. When the left bit, of the charge storage area 107, is programmed, the left bit line 102 acts as a drain and a high programming voltage is supplied therein, and the right bit line 102 acts as a source and is grounded.

Simultaneously, when the right bit of the charge storage area 109, is programmed, the right bit line 102 acts as a drain and a high programming voltage is supplied therein, and the left bit line 102 acts as a source and is grounded.

When the left bit of the charge storage area 107 is read, the left bit line 102 acts as a source, and the right bit line 102 acts as a drain.

Simultaneously, when the right bit of the charge storage area 109, is read, the right bit line 102 acts as a source and the left bit line 102 acts as a drain.

When the bits are erased, the relative position of source and drain are unchanged.

In order to increase the integration of ICs, cell density is increased by reducing the bit line area or the width of the ONO layer. Bit line resistance may increase, however, when the bit line area is reduced, slowing the operating speed of the memory cell. Moreover, when gate length is reduced, specifically, to less than 10 nm, the charge storage areas are subject to cell disturbance during programming, erasing, or reading, therefore, cell density is limited.

### SUMMARY OF THE INVENTION

The present invention is directed to a vertical memory cell with multiple bits and a method for fabricating the same.

Accordingly, the present invention provides a method for fabricating a multi-bit vertical memory cell. A semiconductor substrate having a trench is provided. Doped areas, acting as bit lines, are formed in the semiconductor substrate near its surface and the bottom of the trench. Bit line insulating layers are formed over each of the doping areas. A conformable oxide layer is formed over a sidewall of the trench and the bit line insulating layers to locally store electric charge. A conducting layer is formed over the insulating layer and filled in the trench.

Accordingly, the present invention provides a multi-bit vertical memory cell. The multi-bit vertical memory cell comprises a semiconductor substrate having a trench, bit lines formed in the substrate near its surface and the bottom of the trench, bit line insulating layers disposed over each of the bit lines, a silicon rich oxide layer conformably formed over a sidewall of the trench and the bit line insulating layers to locally store electric charge, and a word line disposed over the silicon rich oxide layer and filled in the trench.

### BRIEF DESCRIPTION OF THE DRAWINGS

For a better understanding of the present invention, reference is made to a detailed description to be read in conjunction with the accompanying drawings, in which:

FIG. 1 shows a conventional NROM cell structure;

FIGS. 2a to 2g are cross-sections showing the method for fabricating a multi-bit vertical memory cell of the present invention;

FIG. 3 is a top view of a memory array;

FIGS. 4a to 4b show a multi-bit vertical memory cell programming of the present invention.

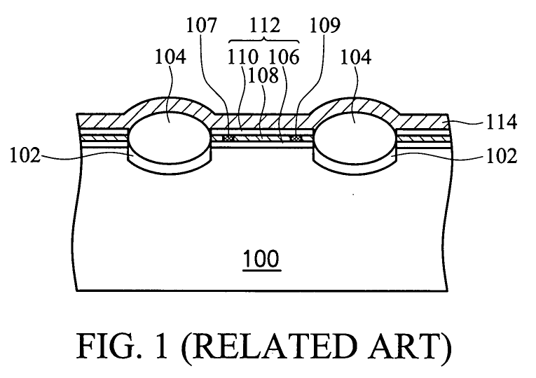

### DETAILED DESCRIPTION OF THE INVENTION

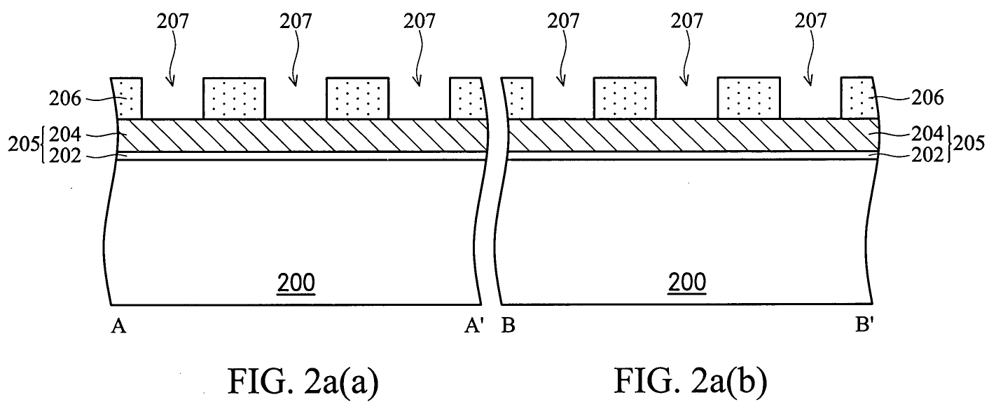

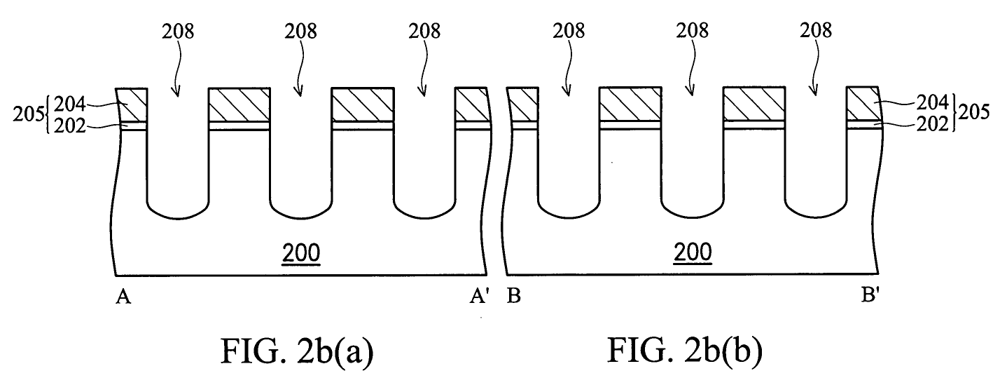

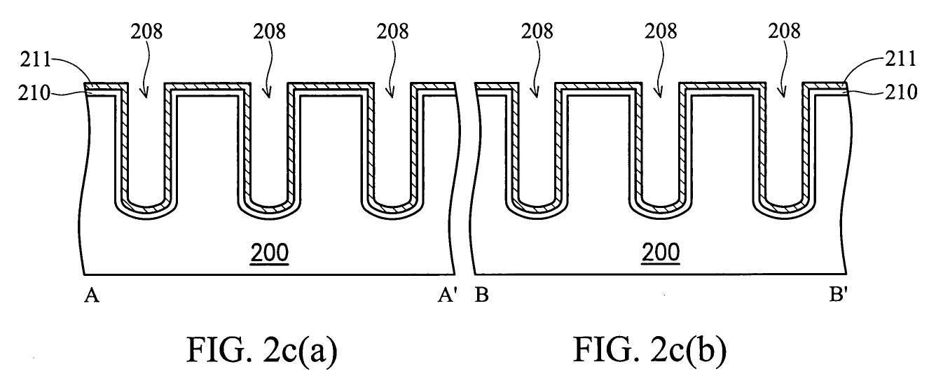

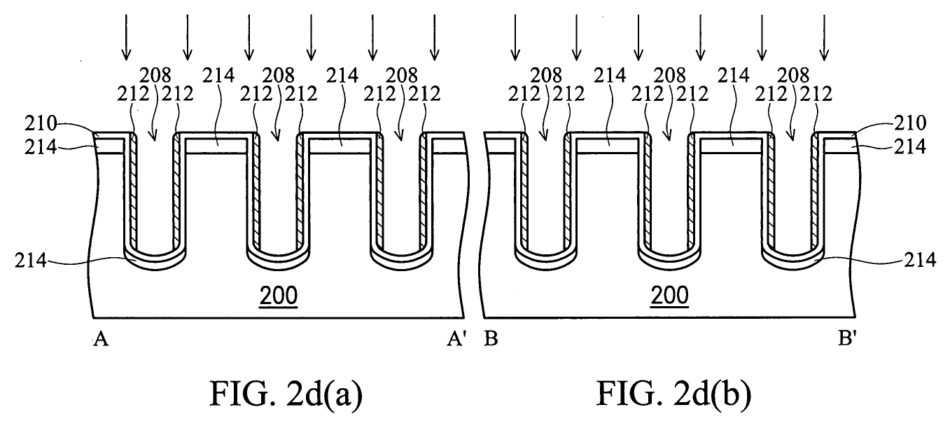

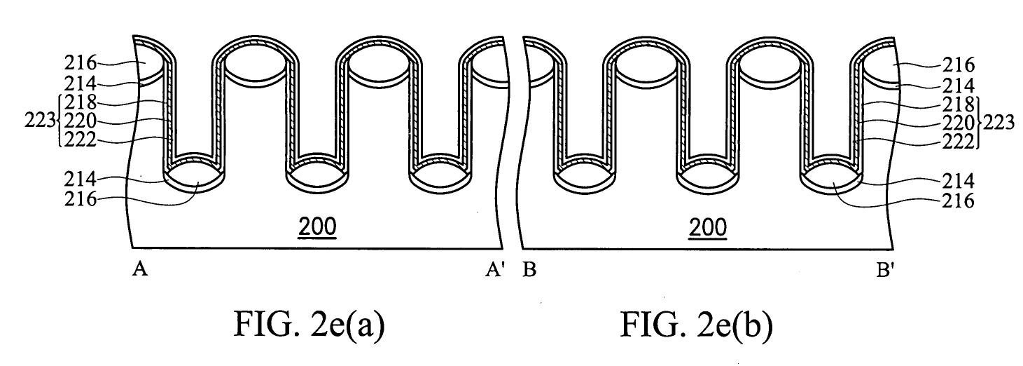

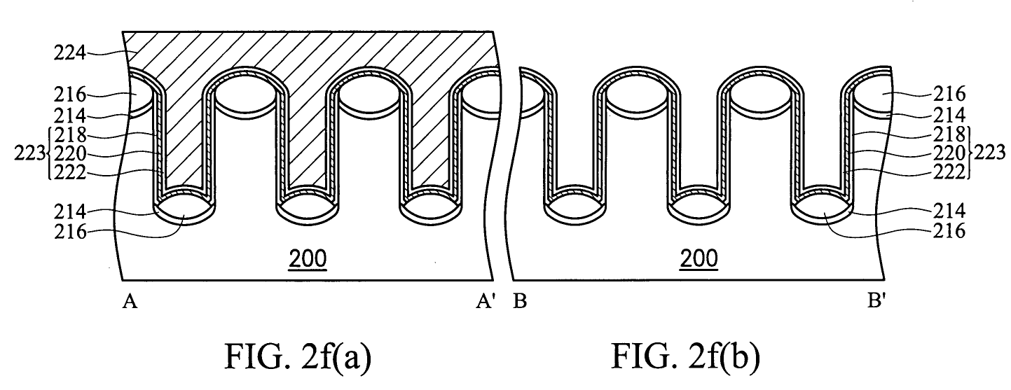

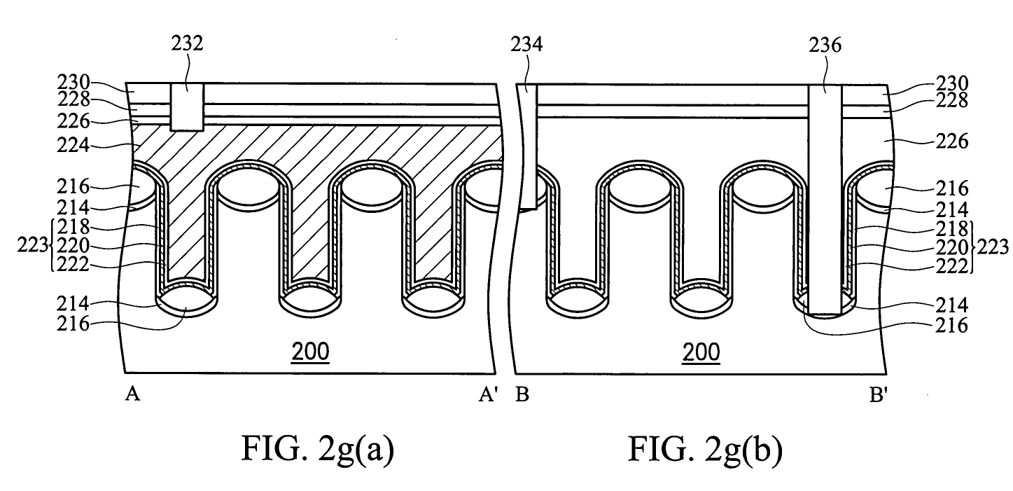

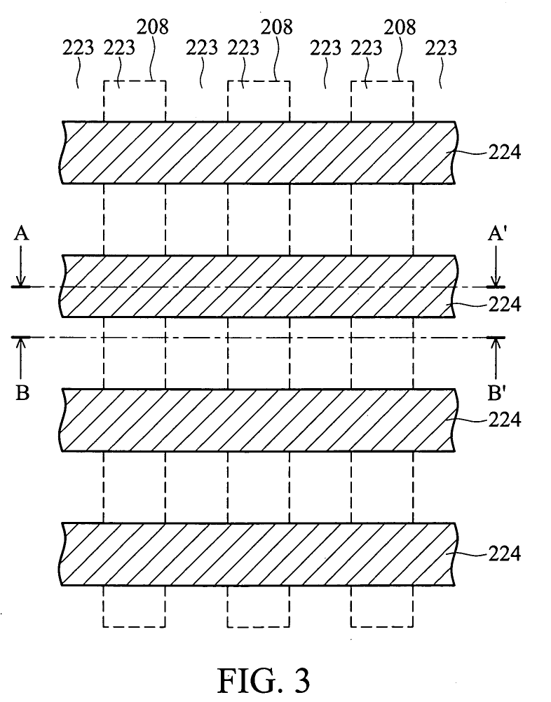

FIGS. 2a to 2g are cross-sections showing the method for fabricating a multi-bit vertical memory cell of the present invention. FIG. 3 is a top view of a memory array. FIGS. 2a to 2g are an 11 cross-section and a 22 cross-section of FIG. 3.

In FIG. 2a, a substrate 200, such as a semiconductor substrate, is provided. A mask layer 205 is formed on the substrate 200. The mask layer 205 can be a single layer or a multiple layers. As shown in FIG. 2a, the mask layer 205 is preferably composed of a pad oxide layer 202 and a thicker silicon nitride layer 204. In this invention, the pad oxide layer 202 can be formed by thermal oxidation or conventional CVD, such as atmospheric pressure CVD (APCVD) or low pressure CVD (LPCVD). The silicon nitride layer 204 overlying the pad oxide layer 202 can be formed by LPCVD using SiCl₂H₂ and NH₃ as reactants. Next, a photoresist layer 206 is coated on the mask layer 205. Thereafter, lithography is performed on the photoresist layer 206 to form openings 207 therein.

In FIG. 2b, the mask layer 205 is anisotropically etched using the photoresist layer 206 as an etching mask by reactive ion etching (RIE) or plasma etching to transfer the pattern of the photoresist layer 206 to the mask layer 205. Thereafter, suitable wet etching or ashing is performed to remove the photoresist layer 206. The semiconductor substrate 200 under these openings is etched to a predetermined depth, such as 1400˜1600 Å, by reactive ion etching or plasma etching to form trenches 208 in the semiconductor substrate 200.

In FIG. 2c, the mask layer 205 is removed by soaking with hot H₃PO₄, and the pad oxide layer 202 is removed by soaking with HF liquid. Thereafter, a silicon oxide layer 210 is conformably formed over the substrate 200 and the surface of the trenches 208 by CVD. A thickness of the silicon oxide layer 210 is 100 Å. This thin oxide layer 210 is used for repairing defects (not shown) formed in the substrate 200 during etching of trenches 208. Next, a silicon nitride layer 211 is deposited over the silicon oxide layer 210 by LPCVD using SiCl2H2 and NH3 as reactants.

In FIG. 2d, the silicon nitride layer 211 is anisotropically etched by RIE or plasma etching to form a spacer 212 over the sidewall of the trenches 208. Thereafter, the bottom of the trenches 208 and the surface of the semiconductor substrate 200 are ion implanted with phosphorus using the spacers 212 as masks. As a result, doping areas 214 are formed in the semiconductor substrate 200 near its surface and the bottom of the trenches 208 acting as bit lines.

In FIG. 2e, bit line insulating layers 216, such as silicon oxide layers, are thermally grown over each of the doping areas 214. The bit line oxides 216 are usually very thick, thereby lowering the bit line capacitance. In this invention, the bit line oxides 216 have a thickness of about 300 to 2000 Å. Thereafter, the spacers 212 and the silicon oxide layer 210 are successively removed by wet etching as well as removing the mask layer 205.

A conformable stack layer 223 is formed on the sidewall of the trenches 208 and the bit line insulating layers 216. In this invention, the stack layer 223 has a silicon rich oxide layer 220 sandwiched between two gate dielectric layers 218 and 222.

A thickness of the silicon rich oxide layer 220 is 50 to 110 Å, and a thickness of the gate dielectric layers 218 and 222 are 50 Å, respectively. Moreover, the gate dielectric layers 218 and 222 can be formed by thermal oxidation. The silicon rich oxide layer 220 can be formed by CVD. As mentioned above, the silicon rich oxide layer 220 in the stack layer 223 is used to store electric charges during memory cell programming. Unlike the prior art, in the invention, the semiconductor substrate 200 of the sidewall of the trenches 208 serves as a vertical channel for a memory cell.

In FIG. 2f, a conductive layer 224, such as a poly layer, is formed over the stack layer 223 and fills in the trenches 208. The thickness of the conductive layer 224 is 1500 to 2000 Å and formed by CVD. Thereafter, the conductive layer 224 can be planarized by chemical mechanical polishing (CMP).

In FIG. 2f(a), a photoresist layer (not shown) having wordline pattern is formed on the conductive layer 224. In FIG. 2f(b), a part of the conducting layer is removed to expose the stack layer 223.

In FIG. 2g, a oxide layer 226, a BPSG layer 228, and a TEOS oxide layer 230 are sequentially formed acting as a ILD layer on the conducting layer 224 and the stack layer 223. The ILD layer is sequentially defined to form word line contact windows and bit line contact windows. The bit line windows are disposed alternately to avoid short between the bit lines. Thereafter, the word line contact windows and the bit line contact windows are filled with a tungsten metal layer to form word line contacts 232 and bit line contacts 234 and 236. The word line contacts 232 are connected to the conducting layer 224, and the bit line contacts 234 and 236 are connected to the doping areas 214.

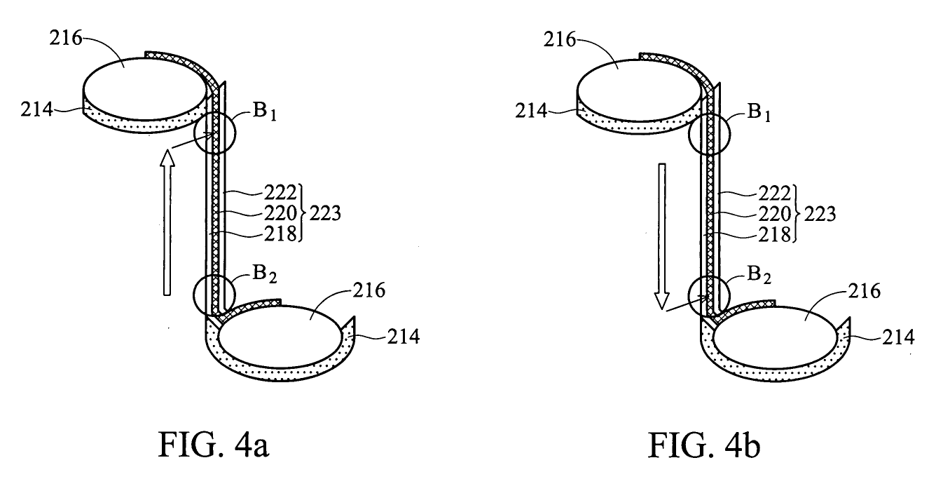

FIGS. 4a to 4b are cross-sections of multi-bit vertical memory cell programming of the present invention.

The memory cell includes a semiconductor substrate 200 having a plurality of trenches 208, and bit lines 214 formed in the semiconductor substrate 200 near its surface and the bottom of the trenches 208. In the invention, the bit lines 214 are formed by phosphorus ion implantation. Bit line insulating layers 216, which have a thickness of about 300 to 2000 Å, are disposed over each of the bit lines 214. A stack layer 223, which includes a silicon rich layer 220, for storing electric charges, sandwiched between two gate dielectric layers 218 and 220, is conformably formed on the sidewall of the trenches 208 and the surface of the bit line insulating layers 216.

In FIG. 4a, the bit line 214 near the trench top acts as a drain, and the bit line 214 in the semiconductor of the trench bottom acts as a source. Thereafter, when a bias voltage is applied, electrons flow to the first bit B1 according to the direction of the arrow and stored locally. Therefore, the first bit B1 is programmed.

In FIG. 4b, the bit line 214 near the trench top acts as a source, and the bit line 214 in the semiconductor of the trench bottom acts as a drain. Thereafter, when a bias voltage is applied, electrons flow to the second bit B2 according to the direction of the arrow and stored locally. Therefore, the second bit B2 is programmed.

Compared with the prior art, the NROM cell of the invention has a vertical channel which prevents the cell disturbance due to the suitable channel length. That is, the length of the channel is based on the depth of the trench. As long as the depth of the trench is deep enough, the cell disturbance can be avoided. Moreover, since the channel of the NROM cell is located in the sidewall of the substrate trench, the entire plane of the substrate can be used to form bit lines by ion implantation. That is, the bit line area can be increased to reduce the resistance of the bit line, thereby increasing the operating speed of the NROM.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A method for fabricating a multi-bit vertical memory cell, comprising:
providing a semiconductor substrate having a trench;
forming doped areas, acting as bit lines, in the semiconductor substrate near its surface and the bottom of the trench;
forming bit line insulating layers over each of the doping areas;
forming a conformable oxide layer over a sidewall of the trench and the bit line insulating layers to locally store electric charge; and
forming a conducting layer over the insulating layer and filling in the trench.

2. The method for fabricating a multi-bit vertical memory cell of claim 1, a fabricating method of the doping areas further comprising:
forming a spacer over the sidewall of the trench; and
performing ion implantation in the substrate using the spacer as a mask; and
removing the spacer.

3. The method for fabricating a multi-bit vertical memory cell of claim 2, wherein the spacer is silicon nitride.

4. The method for fabricating a multi-bit vertical memory cell of claim 2, wherein phosphorous ions are implanted.

5. The method for fabricating a multi-bit vertical memory cell of claim 1, wherein the bit line insulating layers are formed by thermal oxidation.

6. The method for fabricating a multi-bit vertical memory cell of claim 1, wherein the thicknesses of the bit line insulating layers are 300 to 2000 Å.

7. The method for fabricating a multi-bit vertical memory cell of claim 1, wherein the oxide layer is a silicon rich oxide layer.

8. The method for fabricating a multi-bit vertical memory cell of claim 1, wherein the thickness of the oxide layer is 50 to 110 Å.

9. The method for fabricating a multi-bit vertical memory cell of claim 1, further comprising a gate dielectric layer between the oxide layer and the trench surface.

10. The method for fabricating a multi-bit vertical memory cell of claim 9, wherein the gate dielectric layer is a gate oxide layer.

11. The method for fabricating a multi-bit vertical memory cell of claim 9, wherein the thickness of the gate dielectric layer is 50 Å.

12. The method for fabricating a multi-bit vertical memory cell of claim 1, wherein the conducting layer is a poly layer.

13. A multi-bit vertical memory cell, comprising:
a semiconductor substrate having a trench;
bit lines formed in the substrate near its surface and the bottom of the trench;
bit line insulating layers disposed over each of the bit lines;
a silicon rich oxide layer conformably formed over a sidewall of the trench and the bit line insulating layers to locally store electric charge; and
a word line disposed over the silicon rich oxide layer and filled in the trench.

14. The multi-bit vertical memory cell of claim 13, wherein the bit lines are formed by phosphorus ion implantation.

15. The multi-bit vertical memory cell of claim 13, wherein the thicknesses of the bit line insulating layers are 300 to 2000 Å.

16. The multi-bit vertical memory cell of claim 13, wherein the bit line insulating layers are oxide layers.

17. The multi-bit vertical memory cell of claim 13, wherein the thickness of the oxide layer is 50 to 110 Å.

18. The multi-bit vertical memory cell of claim 13, further comprising agate dielectric layer between the silicon rich oxide layer and the trench surface.

19. The multi-bit vertical memory cell of claim 18, wherein the thickness of the gate dielectric layer is 50 Å.

20. The multi-bit vertical memory cell of claim 13, wherein the word line is a poly layer.
